(19) United States
(12) Patent Application Publication
(10) Pub. No.: US 2013/0264577 A1
(43) Pub. Date: Oct. 10, 2013

(54) HIGH FLUX HIGH BRIGHTNESS LED LIGHTING DEVICES

(71) Applicant: AXLEN, INC., Wilmington, DE (US)

(72) Inventors: Li Xu, Saratoga, CA (US); Bo Pi, Carlsbad, CA (US)

(73) Assignee: Axlen, Inc., Wilmington, DE (US)

(21) Appl. No.: 13/858,926

(22) Filed: Apr. 8, 2013

Related U.S. Application Data
(60) Provisional application No. 61/621,488, filed on Apr. 7, 2012.

(51) Int. Cl. H01L 33/60

(52) U.S. Cl. CPC H01L 33/60
USPC 257/76; 257/98; 438/27

(57) ABSTRACT

Methods, systems, and devices are disclosed for implementing high brightness lighting. In one aspect, an LED lighting device includes a substrate capable of dissipating heat, an LED die located on the substrate, an optically reflective structure that is electrically insulative and located on the substrate and structured to form an optically reflective cavity around the LED die, an electrically conductive line structured at least partially within the optically reflective structure and electrically connected to the LED die for electrically driving the LED die to emit the light, a phosphor material located to receive light emitted by the LED die to emit light under optical excitation of the light from the LED die, and an optical element placed in an optical path of the light emitted by the phosphor material to produce better directionality of the emitted light than directionality of emitted light by the phosphor material without the optical element.

### PRIORITY CLAIM

This patent document claims the priority of U.S. provisional application No. 61/621,488 entitled “HIGH FLUX HIGH BRIGHTNESS LED LIGHTING DEVICES” filed on Apr. 7, 2012, the entire disclosure of which is incorporated herein by reference for all purposes.

### TECHNICAL FIELD

This patent document relates to systems, devices, and processes for using light-emitting diodes in lighting devices or lighting fixtures.

### BACKGROUND

A light-emitting diode (LED) is a semiconductor light source. An LED includes semiconducting materials doped with impurities to create a p-n junction, in which electrical current can easily flow one directionally from the p-side (anode) to the n-side (cathode), but not in the reverse direction. Charge-carriers (e.g., electrons and holes) flow into the p-n junction from connecting electrodes at each end of the junction having different voltages. For example, when an electron combines with a hole, the electron falls into a lower energy level and can release energy in the form of a photon, e.g., emitting light. This effect is referred to as electroluminescence. The wavelength of the light emitted, and thus the color of the emitted light, depends on the band gap energy of the materials forming the p-n junction. For example, bright blue LEDs are based on the wide band gap semiconductors including GaN (gallium nitride) and InGaN (indium gallium nitride). LED devices can be used to emit white light that are energy-efficient alternative light sources for replacing some conventional light sources such as incandescent light bulbs and florescent lights. For producing white light using LEDs, one technique is to use individual LEDs that emit three primary colors (red, green, and blue) and then mix all the colors to form white light. Another technique is to use a phosphor material to convert monochromatic light from a blue or ultraviolet LED to broad-spectrum white light, e.g., in a similar manner to fluorescent light bulbs.

A laser diode (LD) is an electrically-pumped semiconductor laser light source. In an LD, the active medium is a solid state semiconductor formed by a p-n junction, e.g., similar to that found in an LED, rather than a gas medium (e.g., in conventional lasing). Laser diodes form a subset of semiconductor p-n junction diodes. For example, a forward electrical bias across the p-n junction of the LD causes the charge carriers to be injected from opposite sides of the p-n junction into the depletion or junction region, e.g., holes are injected from the p-doped component and electrons are injected from the n-doped component of the semiconductor material. As electrons are injected into the diode, the charge carriers combine, some of their excess energy is converted into photons, which interact with more incoming electrons, thereby producing more photons in a self-perpetuating analogous to the process of stimulated emission that occurs in a conventional, gas-based laser. Some examples of conventional LDs include 405 nm InGaN blue-violet laser diodes, e.g., used in in Blu-ray Disc and high definition DVD drive technologies, and 785 nm GaAlAs (gallium aluminum arsenide) laser diodes, e.g., used in Compact Disc (CD) drives.

### SUMMARY

Techniques, systems, and devices are disclosed for implementing LED lighting that produce high brightness.

In one aspect of the disclosed technology, an LED lighting device includes a substrate capable of dissipating heat, an LED die located on the substrate and operable to emit light, an optically reflective structure that is electrically insulative and located on the substrate and structured to form an optically reflective cavity around the LED die to confine the LED die, an electrically conductive line structured at least partially within the optically reflective structure and electrically connected to the LED die for electrically driving the LED die to emit the light, a phosphor material located to receive light emitted by the LED die to emit light under optical excitation of the light from the LED die, and an optical element placed in an optical path of the light emitted by the phosphor material to produce better directionality of the emitted light than directionality of emitted light by the phosphor material without the optical element.

Implementations of the device can optionally include one or more of the following features. For example, the substrate can include a thermal expansion coefficient substantially the same as the material forming the bottom surface of the LED die in contact with the substrate. For example, the optically reflective structure can be configured to reflect visible light with greater than 90% reflectivity. For example, the optically reflective cavity can confine the LED die within an area that is less than 15% than that of the LED die on the substrate. For example, the optically reflective structure can includes a height larger than that of the LED die, and the phosphor material can be located on top of the LED die and within the optically reflective cavity, and in some examples, the optical element can be confined within the optically reflective cavity and cover an opening in the optically reflective cavity existing between the LED die and the optically reflective structure. In other examples, the optical element can be configured to cover at least a portion of the top surface of the optically reflective structure. For example, the optical element can include a thin transparent material layer coupled to the upper surface of the phosphors material and plural optical structures over the thin transparent material layer. In some implementations of the device, for example, the electrically conductive line can be electrically connected to the LED die via wire bonding. In some examples, the optically reflective structure can include an outer slot adjacent to the optically reflective cavity and provide an opening above at least a portion of the electrically conductive line to allow the electrically conductive line to be wire bonded to the LED die. For example, the electrically conductive line can be configured to span from a terminus at the optically reflective cavity to a terminus along an outer surface of the optically reflective structure. In some implementations, for example, the device can further include an electrode structure electrically coupled to the electrically conductive line at the terminus along the outer surface. In some implementations of the device, for example, the optical element can be separated from the phosphor material by a gap region between them. For example, the gap region can be configured to include a distance between the phosphor material and the optical element that is less than a quarter of a height of the LED die from the substrate. In some implementations of the device, for example, the LED lighting device includes two or more LEDs configured in the optically reflective cavity for implementation in an automotive headlamp.

In another aspect, a packaging device for an LED lighting device includes a substrate capable of dissipating heat, the substrate including a region to support one or more LED chips or dies, an optically reflective structure that is electrically insulative on the substrate, the optically reflective structure including a channel at least partially within its interior and a hole that forms an optically reflective well to confine the region to support one or more LED chips or dies, in which the optically reflective well includes an area greater than that of the region and a height greater than that of an LED chip or die placed in the region, in which the channel spans from the hole to an outer surface of the optically reflective structure, an electrically conductive line within the channel of the optically reflective structure, the electrically conductive line, when electrically connected, to provide electrical current to the LED chip or die placed in the region for electrically driving the LED chip or die to emit the light, a wavelength conversion material located within the optically reflective well and above the region, such that when the LED chip or die is placed in the region and operable to emit the light, the wavelength conversion material is capable of receiving the light emitted by the LED chip or die to emit light of one or more different wavelengths than the light emitted from the LED chip or die, and a beam-shaping optical element located in an optical path of the emitted light by the wavelength conversion material to produce better directionality of the emitted light than directionality of emitted light by the wavelength conversion material without the beam-shaping optical element.

Implementations of the packaging device can optionally include one or more of the following features. For example, the packaging device can further include an electrode structure electrically coupled to the electrically conductive line at a terminus along the outer surface. In some implementations of the packaging device, the beam-shaping optical element can be separated from the wavelength conversion material by a gap region between them. In some implementations of the packaging device, the optically reflective structure can be formed of a material including at least one of a plastic material mixed with a titanium oxide constituent, a white ceramic material with an outer titanium oxide coating, or a white Teflon material.

In another aspect, a method to fabricate an LED lighting device capable of producing high optical brightness includes forming an LED die over a substrate capable of dissipating heat, placing an optically reflective material that is electrically insulative on the substrate, the optically reflective material including an electrically conductive line located within and a hole placed over the LED die to form an optically reflective well that confines the LED die, in which an area of the optically reflective well is greater than that of the LED die on the substrate and the optically reflective well includes a height greater than that of the LED die, in which the electrically conductive line spans from a terminus at the hole to a terminus along an outer surface of the optically reflective material, electrically connecting the electrically conductive line to the LED die, depositing a layer of a wavelength conversion material on top of the LED die such that the layer is confined within the optically reflective well, and attaching a beam-shaping optics element formed of a thin layer of a transparent material with plural optical structures over the upper surface of the wavelength conversion material.

Implementations of the method can optionally include one or more of the following features. For example, in some implementations of the method, the depositing the layer of the wavelength conversion material can be implemented to cover an opening in the optically reflective well existing between the LED die and the optically reflective material. For example, the attaching the beam-shaping optics element can be implemented to cover at least a portion of the top surface of the optically reflective material, which in some examples, the beam-shaping optics element can also be confined within the optically reflective well and cover the opening. For example, the beam-shaping optics element can be separated from the wavelength conversion material by a gap area between them, e.g., in which the gap area can include a distance between the wavelength conversion material and the beam-shaping optics element that is less than a quarter of a height of the LED die from the substrate. For example, in some implementations of the method, the electrically connecting can include wire bonding the electrically conductive line to the LED die.

In another aspect, a method to fabricate a high brightness LED lighting device includes forming an LED die over a substrate capable of dissipating heat, forming electrically conductive lines on the substrate, placing an optically reflective material that is electrically insulative on the substrate, the optically reflective material including a channel on the bottom surface located over the electrically conductive lines and a hole placed over the LED die to form an optically reflective well that confines the LED die, in which an area of the optically reflective well is greater than that of the LED die on the substrate and the optically reflective well includes a height greater than that of the LED die, in which the electrically conductive line spans through the channel from a terminus at the hole to a terminus along an outer surface of the optically reflective material, electrically connecting the electrically conductive line to the LED die, depositing a layer of a wavelength conversion material on top of the LED die such that the layer is confined within the optically reflective well, and attaching a beam-shaping optics element formed of a thin layer of a transparent material with plural optical structures over the upper surface of the wavelength conversion material.

Implementations of the method can optionally include one or more of the following features. For example, in some implementations of the method, the depositing the layer of the wavelength conversion material can be implemented to cover an opening in the optically reflective well existing between the LED die and the optically reflective material. For example, the attaching the beam-shaping optics element can be implemented to cover at least a portion of the top surface of the optically reflective material, which in some examples, the beam-shaping optics element can also be confined within the optically reflective well and cover the opening. For example, the beam-shaping optics element can be separated from the wavelength conversion material by a gap area between them, e.g., in which the gap area can include a distance between the wavelength conversion material and the beam-shaping optics element that is less than a quarter of a height of the LED die from the substrate. For example, in some implementations of the method, the electrically connecting can include wire bonding the electrically conductive line to the LED die.

The subject matter described in this patent document can be implemented in specific ways that provide one or more of the following features. For example, LED lighting devices of the disclosed technology include optical designs that change light distribution and provide photon recycling can be used to improve optical efficiency and output brightness. For example, an exemplary optical packaging design for an LED lighting device includes beam shaping optics including a micro structured optical film structure that can be used in combination with LEDs and/or phosphor layers or films to produce a smaller angular light distribution, e.g., as compared to standard Lambertian angular output directly from a phosphor layer in an LED lighting device. For example, with a well-controlled size of the emitting light from the phosphors layer, the Etendue of the system with the beam shaping optics can be smaller than a system without such beam shaping optics. The exemplary optical packaging design can provide a minimum loss in the photon recycling in phosphors, and the brightness of this LED lighting device can be increased.

### BRIEF DESCRIPTION OF THE DRAWINGS

FIG. 1A shows an LED lighting device with increased brightness based on an exemplary LED packaging design of the disclosed technology.

FIG. 1B shows another exemplary LED packaging design for an LED lighting device similar to that in FIG. 1A.

FIGS. 2A and 2B show other exemplary packaging designs for an LED lighting device.

FIGS. 3A and 3B show other exemplary packaging designs for an LED lighting device.

FIGS. 4A and 4B show other exemplary packaging designs for an LED lighting device.

Like reference symbols and designations in the various drawings indicate like elements.

### DETAILED DESCRIPTION

For lighting applications that demand high optical power, discharge lamps and particularly high intensity discharged lamps (HID) can produce high optical output power (e.g., high flux output and high brightness with large lumens from very small discharge arcs) that may be difficult to match by the output power of some existing commercial LED devices. Attempts have been made by using densely packaged multiple LED chips to produce high flux output and high brightness by driving the LED chips at high current density levels, e.g., greater than 1 A/mm² LED chips driven under such high currents can present technical issues in properly dissipating the large amounts of heat generated by the LED chips. Therefore, lighting devices based on LED technology can face a number of technical issues, including, for example, providing LED designs in lighting devices for high performance LED chips that can handle high current density and high temperature, or providing good thermal packages to such LED chips to reduce the high heat and extend the lifetime of these hard-driven LED chips. In addition, secondary optics can be placed around LED and phosphors base to collect and further shape the light. Such optics may be required to collect large angle of light due to the near Lambertian feature of LED light sources and thus can be expensive to manufacture.

Techniques, systems, and devices are disclosed for implementing LED lighting that produce high brightness. High brightness as referred to in this patent document can be defined by the optical flux divided by light source area and emission angle (solid angle). Examples of LED lighting sources the present technology are described herein that include using optically reflective structures to confine the LED die and phosphors to produce a small light source area or footprint and combining such optically reflective structures with nano-optics structures that enhance the output light directionality to reduce the emission angle. This combination can be used to produce high brightness in LED lighting devices without overdriving the LED chips at high currents that cause heat management issues.

Examples of light emitting devices with controllable angular light emitting distribution based on a coating of a thin layer of transparent material with defined geometric structure on the top of wavelength conversion material on LED are described in the PCT Patent Application document WO 2011/163672, entitled “ADJUSTABLE SOLID STATE ILLUMINATION MODULE HAVING ARRAY OF LIGHT PIXELS”, which is incorporated by reference in its entirety as part of the disclosure in this patent document. The advantages of this optical beam shaping technology include its compactness, material saving, and Etendue reservation or reduction. Such optical designs can be combined with LED lighting packaging designs disclosed herein to achieve an LED device package that holds one or multiple LEDs with phosphors and optical beam shaping technology for achieving high brightness in the output.

In one aspect of the disclosed technology, a lighting device includes a heat sink plate that dissipates heat, an LED die on the heat sink plate and operable to emit light, an optically reflective structure located on the heat sink plate and around the LED die to confine the LED die, a phosphor material located to receive light emitted by the LED die to emit light under optical excitation of the light from the LED die, and an optical element placed in an optical path of the light emitted by the phosphor material to produce better directionality of the emitted light than directionality of emitted by the phosphor material without the optical element.

In another aspect, an LED lighting device includes a substrate capable of dissipating heat, an LED die located on the substrate and operable to emit light, an optically reflective structure that is electrically insulative and located on the substrate and around the LED die to confine the LED die, an electrically conductive line structured at least partially within the optically reflective structure and electrically connected to the LED die for electrically driving the LED die to emit the light, a phosphor material located to receive light emitted by the LED die to emit light under optical excitation of the light from the LED die, and an optical element placed in an optical path of the light emitted by the phosphor material to produce better directionality of the emitted light than directionality of emitted light by the phosphor material without the optical element.

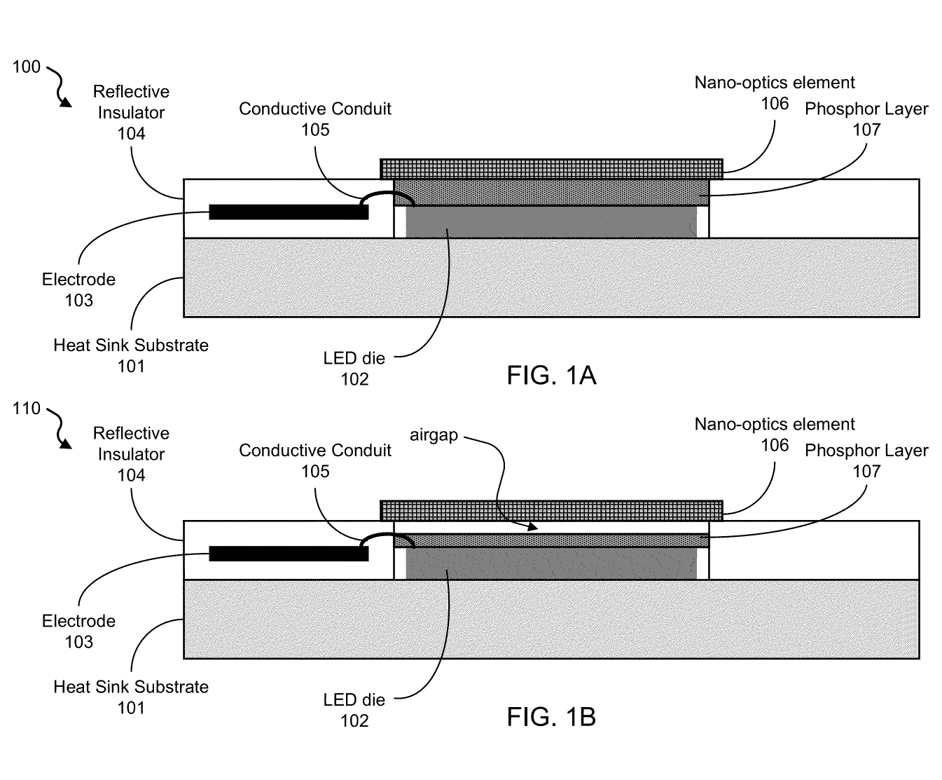

FIG. 1A shows a diagram of an LED lighting device 100 with increased brightness based on an exemplary LED chip package design of the disclosed technology that places an LED chip or die on a substrate which has similar thermal expansion as the LED chip or die and within an optically reflective cavity or well covered by a phosphor layer and/or optical elements to produce high optical output. The diagram of FIG. 1A represents a cross-section of the LED lighting device 100. In this example, the LED lighting device 100 includes a flat substrate 101 capable of dissipating heat, e.g., such as a heat sink plate. The LED lighting device 100 includes an LED chip or die 102 operable to emit light that is attached to the substrate 101. For example, the substrate 101 can be formed of a ceramic material, e.g., aluminum nitride (AlN), or a metal alloy material, e.g., copper tungsten (CuW). The material of the substrate 101 can be selected to have a similar thermal expansion coefficient as the LED chip or die substrate, providing good thermal conductivity for better heat dissipation. In some implementations, for example, the substrate 101 can include lead-frames. Also, in some implementations, the LED chip or die 102 can be attached to the substrate 101 by solder (e.g., eutectic solder).

The LED lighting device 100 includes an optically reflective insulator structure 104 having high optical reflectance (e.g., greater than 90%) for visible light. The optically reflective insulator structure 104 is configured on the heat sink substrate 101 and around the LED chip or die 102, e.g., to physically confine the LED chip or die 102. In some implementations, the optically reflective insulator structure 104 is structured to form a region around the LED chip or die 102 with an opening slightly larger than the LED chip or die 102 (e.g., less than 15% in size) and include a height that is above the LED chip or die 102. For example, the optically reflective insulator structure 104 can confine the light output of the LED chip or die 102 without much increase of size of an LED chip (e.g., less than 25%). Materials for the optically reflective insulator structure 104 can include, for example, plastic mixed with titanium oxide (TiO₂), white ceramic with a thin TiO₂ coating, or white Teflon, among other examples.

In some implementations of the LED lighting device 100, the optically reflective insulator structure 104 can include an interior region to allow an electrically conductive line or electrode 103 to be positioned near and connected to the LED chips and/or dies 102 by an electrically conductive conduit 105. For example, the electrically conductive line or electrode 103 can be made from mold conductive metal electrodes directly in the optically reflective insulator structure 104 material. For example, the electrically conductive conduit 104 can be formed via wire bonding. The electrically conductive lines or electrodes 103 are structured to include a pathway to an external surface of the LED lighting device 100 to provide an electrical interface with an external circuit and/or power source.

The LED lighting device 100 includes a thin layer of a wavelength conversion material 107, e.g., one or more phosphor layers, deposited on the surface of the LED chip or die 102 and confined within the reflective structure opening. For example, the wavelength conversion material layer 107 can be formed to cover the entire opening area over the LED chip or die 102 and between the walls formed by the optically reflective insulator structure 104. Thus, under this exemplary design, the LED and the wavelength conversion materials are confined in the optically reflective cavity or well of the LED lighting device 100. For example, in some implementations, the LED lighting device 100 can be configured such that the LED chip or die 102 include blue and/or UV LEDs (e.g., GaN based) that combine with the wavelength conversion material 107 to produce white light that is emitted out of the reflective structure opening.

The LED lighting device 100 includes a beam-shaping optics element 106 placed on the wavelength conversion material 107 and the top surface of the optically reflective insulator structure 104. In some examples, the beam-shaping optics element 106 can be configured as a nano-optics element including a thin layer of transparent material (e.g., such as high temperature polymers or glasses) to visible light with plural optical structures on the surface of the thin transparent layer, which is described in further detail in the patent document PCT Patent Application WO 2011/163672. The exemplary beam-shaping optics element 106 can be created by nano-imprint technology or precision molding, among other techniques. In some implementations, the beam-shaping optics element 106 (e.g., the thin layer of the transparent layer with the plural optical structures) is optically bonded to wavelength conversion material 107 or bonded via index matching gel/epoxy.

FIG. 1B shows another design of an LED lighting device 110 structured similar to the LED lighting device 100 in FIG. 1A, with some modifications to the interface between the wavelength conversion material 107 and the beam-shaping optics element 106. The LED lighting device 110 includes a thin layer of air (e.g., less than 500 μm, or in some implementations, less than 300 μm) formed between the wavelength conversion material 107 and the beam-shaping optics element 106. This air gap can be located within the high reflective wall. In some implementations, for example, the thin layer of air can be configured to be thin, e.g., less than ¼^{th} of the LED size. In some implementations, for example, the thin layer of air can be configured to be less than 300 μm.

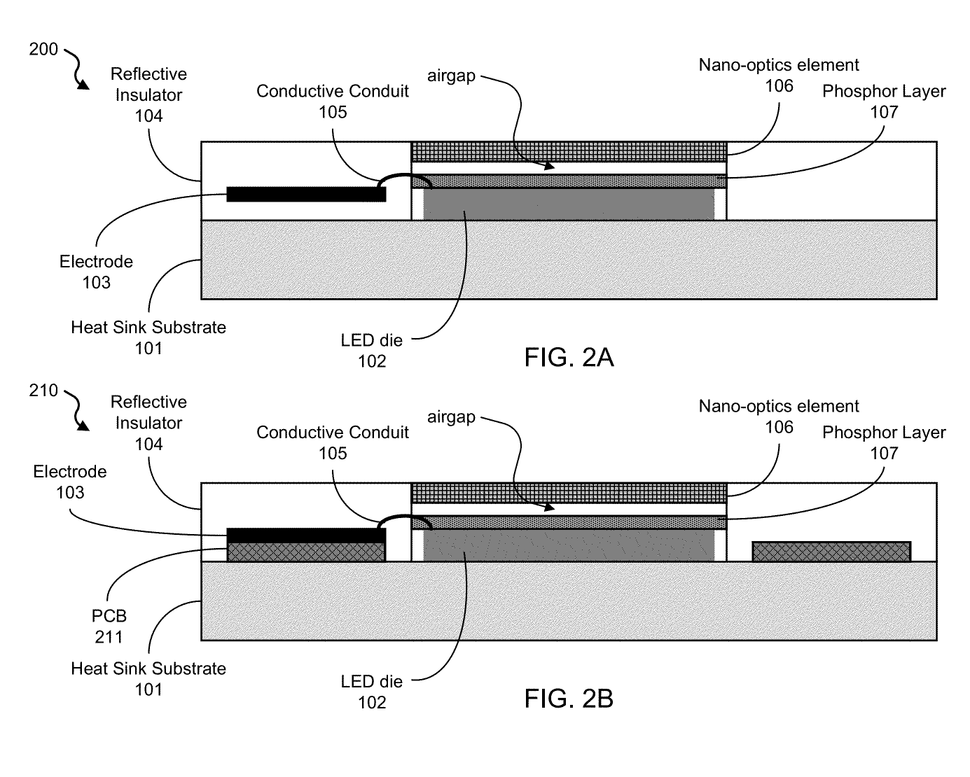

FIG. 2A shows another design of an LED lighting device 200 structured similar to the LED lighting device 110 in FIG. 1B with some modifications, in which the beam-shaping optics element 106 is placed inside the optically reflective cavity or well. In some implementations, the LED lighting device 200 can be configured to include the thin layer of air (e.g., the air gap) between the wavelength conversion material 107 and the beam-shaping optics element 106 in the cavity. In other implementations, the LED lighting device 200 does not include the air gap, and the beam-shaping optics element 106 is directly interfaced with the wavelength conversion material 107.

FIG. 2B shows another design of an LED lighting device 210 structured similar to the LED lighting device 200 in FIG. 2A with some modifications, in which the LED lighting device 210 includes a thin printed circuit board (PCB) with electrically conductive pathways placed proximate the LED chip or die 102 and electrically connected to the LED chip or die 102 via the electrically conductive conduit 105, e.g., via wire bonded wire. In some examples, a flex circuit board can also be used to replace PCB. Also for example, in some implementations, the LED lighting device 210 can be configured to include the air gap between the wavelength conversion material 107 and the beam-shaping optics element 106 in the cavity, or in other implementations, the LED lighting device 210 does not include the air gap.

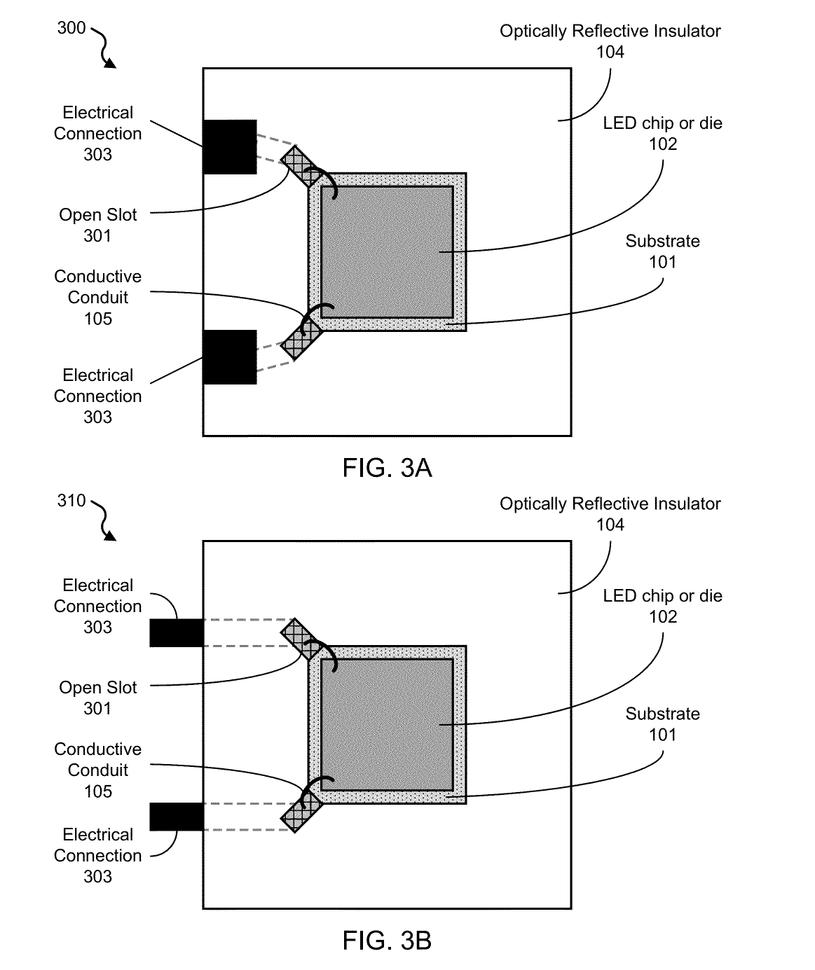

FIGS. 3A and 3B illustrate other examples of an LED lighting device with increased brightness. The diagrams of FIGS. 3A and 3B represents a top of the exemplary LED lighting devices. FIG. 3A shows a diagram of an LED lighting device 300 that includes one or more open slots 301 to allow for wire bonding the electrical connection of the electrically conductive conduit 105 to the LED chip or die 102 and the electrically conductive line or electrode 103. For example, the open slot 301 provides an exposed region of the electrically conductive line or electrode 103 from the optically reflective insulator 104 to enable the formation of the conductive conduit 105 to the LED chip or die 102. The LED lighting device 300 also includes one or more electrical connections 303 structured on the top surface of the optically reflective insulator 104 and electrically coupled to the electrically conductive line or electrode 103 to provide an interface for the device 300 and an external circuit and/or power source. Like the LED lighting device 100 in FIG. 1A, the LED lighting device 300 includes the optically reflective cavity or well to confine the LED chip or die 102 and the wavelength conversion material 107 with the beam-shaping optics structures (not shown in the diagram of FIG. 3A) that enhance the output light directionality of the LED lighting device 300. For example, the optically reflective insulator 104 is structured to be should also taller than the LED chip or die 102 so that the wavelength extension material 107 can also be confined. In some implementations of the LED lighting device 300, the beam-shaping optics element 106 thin layer can be placed on top of the wavelength extension material 107 and a portion of the optically reflective insulator structure 104 to cover the gap or opening between the LED chip or die 102 and the optically reflective insulator 104. In other implementations of the LED lighting device 300, the beam-shaping optics element 106 thin layer can be placed on top of the wavelength extension material 107 and within the cavity or well formed by the optically reflective insulator structure 104, for example, similar to the LED lighting device 200. Also for example, in some implementations, the LED lighting device 300 can be configured to include the air gap between the wavelength conversion material 107 and the beam-shaping optics element 106 in the cavity, or in other implementations, the LED lighting device 300 does not include the air gap.

FIG. 3B shows another design of an LED lighting device 310 structured similar to the LED lighting device 300 in FIG. 3A with some modifications, in which the one or more electrical connections 303 are structured to protrude out of the side of the device 310 from the interior region of the optically reflective insulator 104 containing the electrically conductive line or electrode 103. The electrical connections 303 can provide an interface for the device 310 with an external circuit and/or power source.

Some lighting applications demand high brightness, including automobile headlights, aircraft or other vehicle headlights, theatre spot lights, among others. For example, car headlamps may require 1,000 lm per lamp with a focus capability for small Etendue due to beam requirements of less than 6 sq mm for the Lambertian source. Meeting such demands can be challenging for regular LED chips having output of 200 lm/sq mm. For example, driving the LED chip (e.g., 1 mm chip) at high current densities, e.g., greater than 1 A/sq mm (or ˜3 W per mm), can produce the desired brightness but usually requires an expensive LED package to manage the heat produced by driving such high current densities as well as expensive secondary optics to collect light at wide angles, e.g., large angles up to 180 degrees.

The disclosed technology can provide LED lighting solutions that meet such demands for automobile headlamps. For example, the disclosed LED lighting device packages include proper nano-optics can be designed to reduce LED (white) Etendue by 50% or more without significant loss of light output and, with improved output optical brightness, relatively small current density, e.g., by 50% per LED, may be achieved. Also for example, using the disclosed LED lighting device packages, low-current LED chips can be used to achieve higher efficiency in electrical-to-optical conversion (lm/W) due to lower current density, reducing the cost of the LED lighting device (e.g., due to lower thermal resistance requirements. Additionally the disclosed LED lighting device packages include low cost secondary optics for headlamp applications, e.g., due to <120 degree collecting optics.

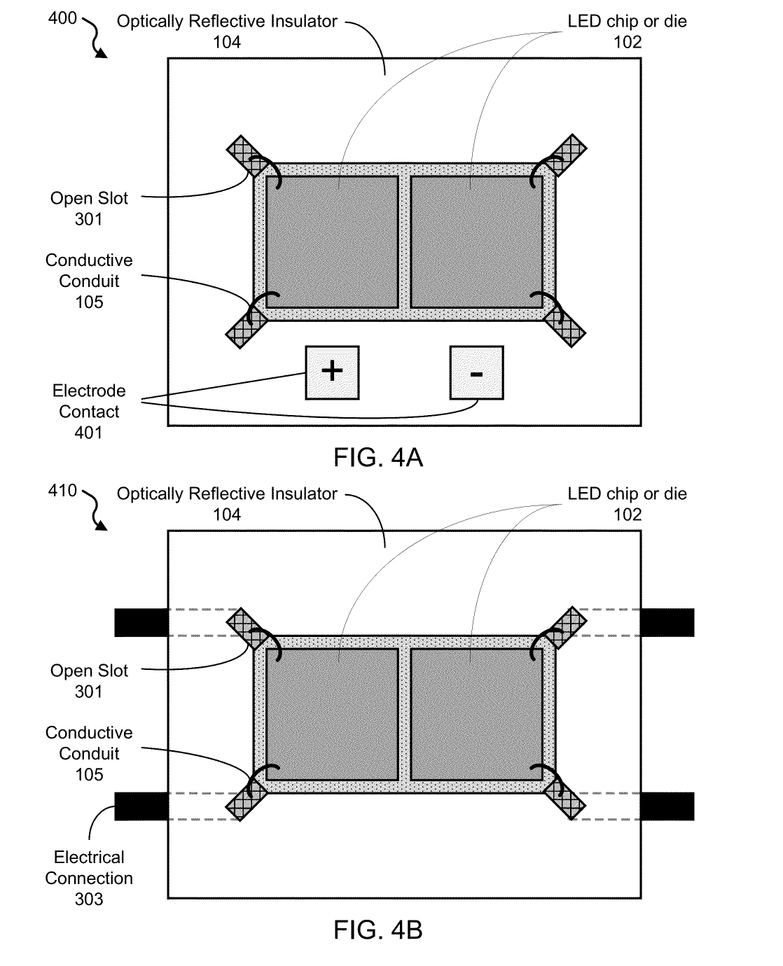

FIGS. 4A and 4B show other examples of LED chip packaging designs for LED headlamp devices with increased brightness, e.g., including for automotive headlamps. FIG. 4A shows an LED lighting device 400 that includes multiple LED chips or dies 102 (e.g., blue or UV) attached to the flat substrate 101 having a thermal conductivity similar to the thermal expansion coefficient of the substrate of the LED chips. In one example, the LEDs chips or dies 102 can be spaced uniformly apart in a two dimensional arrangement or a one dimensional line on the heat sink substrate 101. In another exemplary configuration, the LEDs 102 can be arranged nonuniformly on the substrate 101. For example, an exemplary nonuniform arrangement can include different groupings of LEDs (e.g., in subgroups) that have a particular spacing between the subgroups that is not equivalent to the spacing between the LEDs within each subgroup. In some implementations, the multiple LED chips or dies 102 can be organized in various configurations within one or more optically reflective cavities of the LED lighting device 400. As in the example shown in FIG. 4A, two or more LED chips or dies 102 can be configured per cavity of the LED lighting device 400.

In some implementations, the multiple LED chips or dies 102 are closed packaged to each other, e.g., such that there is a gap between adjacent chips that is less than 20% of the individual LED chip size. The LED lighting device 400 includes the optically reflective insulator structure 104 (e.g., >90% for visible light) structured to form the optically reflective cavity confining the LEDs, the optically reflective insulator structure 104 including the opening slightly larger than the LED array (e.g., less than 25% in size) and height that is above the LED chips or dies 102 placed on the substrate 101, as described above. The LED lighting device 400 includes the wavelength conversion material 107 that can be deposited as a thin layer over the surface of the LED chips or dies 102, in which the wavelength conversion material 107 is confined within the opening of the optically reflective insulator structure 104, and the beam-shaping optics element 106 placed on top of the wavelength extension material 107 and over the perimeter of the cavity formed by the optically reflective insulator 104 (e.g., similar to the LED lighting device 100 of FIG. 1A) or placed on top of the wavelength extension material 107 and within the optically reflective cavity (e.g., similar to the LED lighting device 200 of FIG. 2A). Also for example, in some implementations, the LED lighting device 400 can be configured to include the air gap between the wavelength conversion material 107 and the beam-shaping optics element 106 in the cavity, or in other implementations, the LED lighting device 400 does not include the air gap.

The LED lighting device 400 includes the open slots 301 to allow for wire bonding the electrical connection of the electrically conductive conduit 105 to the multiple LED chips or dies 102 and the electrically conductive line or electrode 103 formed within the interior of the optically reflective insulator structure 104. The open slots 301 expose a region of the electrically conductive line or electrode 103 from the optically reflective insulator 104 to enable the formation of the conductive conduit 105 to each of the multiple LED chips or dies 102 (e.g., in the array). The LED lighting device 400 also includes electrode contacts 401 including a positive and negative electrode terminal and structured on the top surface of the optically reflective insulator 104 and electrically coupled to the respective electrically conductive lines 103 to provide an interface for the device 400 and an external circuit and/or power source.

In one example, the described technology based on optically reflective structural configurations and nano-optics can be used to provide an automotive LED lighting device with the following features and properties. LED chips such as blue GaN LEDs including a 60 mil (e.g., 1.4 mm), 2 mm² area can be used; chip driving conditions can include a current density of 500 mA/mm², 3 W per chip or 1.5 W per mm²; lumen efficacy can be greater than 100 lm/W; lumen output can be 300 lm per chip; and four LED chips can be used to achieve a 1,200 lm headlamp.

In another example, the described technology based on optically reflective structural configurations and nano-optics can be used to provide an automotive LED lighting device with the following features and properties. LED chips such as blue GaN LEDs including a 85 mil (2.1 mm), 4 mm² area can be used; chip driving conditions can include a current density of 500 mA/mm², 6 W per chip; lumen efficacy can be greater than 100 lm/W; lumen output can be 600 lm per chip; and two LED chips can be used to achieve the 1,200 lm headlamp.

In yet another example, the described technology based on optically reflective structural configurations and nano-optics can be used to provide an automotive LED lighting device with the following features and properties. LED chips such as blue GaN LEDs including a 40 mil (1 mm), 1 mm² area; chip driving conditions can include a current density of 500 mA/mm², 1.5 W per chip; lumen efficacy can be greater than 100 lm/W; lumen output can be 150 lm per chip; and eight chips can be used to achieve the 1,200 lm headlamp.

FIG. 4B shows another design of an LED lighting device 410 structured similar to the LED lighting device 400 in FIG. 4A with some modifications, in which the one or more electrical connections 303 are structured to protrude out of the side of the device 410 from the interior region of the optically reflective insulator 104 containing the electrically conductive line or electrode 103. The electrical connections 303 can provide an interface for the device 410 with an external circuit and/or power source.

Based on the described technology, the following devices can also be implemented.

In one exemplary embodiment, an LED lighting device can include an excitation light source; a wavelength conversion material that absorbs light from excitation light source and emits longer wavelength light; a reflective structure to visible light that has opening which is slightly larger than the excitation light source (e.g., less than 15%) and taller than the excitation light source (e.g., not more than by 1 mm); and a layer of transparent material that has a plural optical structure in contact to or is in close proximity to the wavelength conversion material. In some implementations, the transparent layer with the plural optical structure has same size or slightly larger size than that of the wavelength conversion layer, and each of the plural optical structures in the transparent layer has base and apex that is smaller than the base. In some implementations, the base of each of the plural optical structures in the transparent layer has at least one dimension larger than 1 μm but smaller than ¼^{th} of the size of the light conversion material. In some implementations, the transparent layer with the plural optical structure is optically bonded to wavelength conversion material or through index matching gel/epoxy. In some implementations, the transparent layer with plural optical structure is in close proximity to wavelength conversion material with an air gap that is smaller than ¼^{th} size of LED die. In some implementations, the device can include light collecting optics that collects majority of the output light (e.g., greater than 55%). The light collecting optics may be configured as an optical waveguide (e.g., such as a fiber, but not limited to) with a similar optical input acceptance angle to the emission angle from the transparent layer with the plural optical structure (e.g., within 75%).

In another exemplary embodiment, an LED lighting device can include an excitation light source; a wavelength conversion material that absorbs light from the excitation light source and emits longer wavelength light; a layer of transparent material that has a plural optical structure configured in contact to or in close proximity to the wavelength conversion material; a light collecting optical assembly to collect light from the excitation light source and deliver the light onto the wavelength conversion material; and a color filter that passes the light from excitation light source but reflects longer wavelength from wavelength extension material, where the filter is located near the wavelength conversion material and between the light collecting optics and wavelength extension material. In some implementations, the device can implement the light excitation source by multiple LEDs or LDs, and the light collecting optical assembly includes focusing optics that combine multiple LED light output and condenses it onto the light conversion material.

In another aspect of the disclosed technology, a packaging device for an LED lighting device includes a substrate capable of dissipating heat, the substrate including a region to support one or more LED chips or dies, an optically reflective structure that is electrically insulative on the substrate, the optically reflective structure including a channel at least partially within its interior and a hole that forms an optically reflective well to confine the region to support one or more LED chips or dies, in which the optically reflective well includes an area greater than that of the region and a height greater than that of an LED chip or die placed in the region, in which the channel spans from the hole to an outer surface of the optically reflective structure, an electrically conductive line within the channel of the optically reflective structure, the electrically conductive line, when electrically connected, to provide electrical current to the LED chip or die placed in the region for electrically driving the LED chip or die to emit the light, a wavelength conversion material located within the optically reflective well and above the region, such that when the LED chip or die is placed in the region and operable to emit the light, the wavelength conversion material is capable of receiving the light emitted by the LED chip or die to emit light of one or more different wavelengths than the light emitted from the LED chip or die, and a beam-shaping optical element located in an optical path of the emitted light by the wavelength conversion material to produce better directionality of the emitted light than directionality of emitted light by the wavelength conversion material without the beam-shaping optical element.

Implementations of the packaging device can optionally include one or more of the following features. For example, the packaging device can further include an electrode structure electrically coupled to the electrically conductive line at a terminus along the outer surface. In some implementations of the packaging device, the beam-shaping optical element can be separated from the wavelength conversion material by a gap region between them. In some implementations of the packaging device, the optically reflective structure can be formed of a material including at least one of a plastic material mixed with a titanium oxide constituent, a white ceramic material with an outer titanium oxide coating, or a white Teflon material.

In another aspect of the disclosed technology, a method to fabricate an LED lighting device capable of producing high optical brightness includes forming an LED die over a substrate capable of dissipating heat, placing an optically reflective material that is electrically insulative on the substrate, the optically reflective material including an electrically conductive line located within and a hole placed over the LED die to form an optically reflective well that confines the LED die, in which an area of the optically reflective well is greater than that of the LED die on the substrate and the optically reflective well includes a height greater than that of the LED die, in which the electrically conductive line spans from a terminus at the hole to a terminus along an outer surface of the optically reflective material, electrically connecting the electrically conductive line to the LED die, depositing a layer of a wavelength conversion material on top of the LED die such that the layer is confined within the optically reflective well, and attaching a beam-shaping optics element formed of a thin layer of a transparent material with plural optical structures over the upper surface of the wavelength conversion material.

In some exemplary embodiments of the method, the method to fabricate an LED lighting device capable of producing high optical brightness, e.g., such as the LED lighting devices 100 and/or 110 includes a process to attach an LED chip or die (e.g., the LED chip or die 102) to a flat substrate with good thermal conductivity (e.g., heat sink substrate 101) that has similar thermal expansion coefficient as the LED chip substrate. The method includes a process to form a high optically reflective structure (e.g., greater than 90% in reflectivity for visible light, such as the optically reflective insulator 104) on the thermally conductive flat substrate such that the high optically reflective structure forms an opening slightly larger than the attached LED chip or die (e.g., less than 15% in size) and a height that is above the LED chip or die. The method includes a process to deposit a thin layer of wavelength conversion material (e.g., the phosphor layer 107) on the top surface of the LED chip or die such that the layer is confined within the reflective structure opening. The method includes a process to attach a beam-shaping optics element (e.g., the nano-optics element 106 or other thin layer transparent material with plural optical structures) over the top surface of the wavelength conversion material and on a portion of the top surface of the high optically reflective structure such that the beam-shaping optics element covers the opening region between the LED chip or die and the high optically reflective structure.

In some implementations, the process to attach the beam-shaping optics element can include forming a thin region of an air gap (e.g., less than ¼^{th} of the LED size) between the wavelength conversion material and the transparent layer with plural optical structures. In some implementations, the process to form the high optically reflective structure includes forming a high optically reflective and electrically insulative structure on the thermally conductive flat substrate to confine the attached LED chip or die, in which the high optically reflective and electrically insulative structure includes an electrode formed within an interior region of the optically reflective insulator structure. For example, the electrode can be made from mold conductive metal electrodes directly in the optically reflective insulator structure.

In another aspect of the disclosed technology, a method to fabricate a high brightness LED lighting device includes forming an LED die over a substrate capable of dissipating heat, forming electrically conductive lines on the substrate, placing an optically reflective material that is electrically insulative on the substrate, the optically reflective material including a channel on the bottom surface located over the electrically conductive lines and a hole placed over the LED die to form an optically reflective well that confines the LED die, in which an area of the optically reflective well is greater than that of the LED die on the substrate and the optically reflective well includes a height greater than that of the LED die, in which the electrically conductive line spans through the channel from a terminus at the hole to a terminus along an outer surface of the optically reflective material, electrically connecting the electrically conductive line to the LED die, depositing a layer of a wavelength conversion material on top of the LED die such that the layer is confined within the optically reflective well, and attaching a beam-shaping optics element formed of a thin layer of a transparent material with plural optical structures over the upper surface of the wavelength conversion material.

It is understood that the described LED packaging designs and fabrication techniques can also be implemented using LD chips and/or dies.

While this patent document contains many specifics, these should not be construed as limitations on the scope of any invention or of what may be claimed, but rather as descriptions of features that may be specific to particular embodiments of particular inventions. Certain features that are described in this patent document in the context of separate embodiments can also be implemented in combination in a single embodiment. Conversely, various features that are described in the context of a single embodiment can also be implemented in multiple embodiments separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. Moreover, the separation of various system components in the embodiments described in this patent document should not be understood as requiring such separation in all embodiments.

Only a few implementations and examples are described and other implementations, enhancements and variations can be made based on what is described and illustrated in this patent document.

What is claimed is:

1. A light-emitting diode (LED) lighting device, comprising:
a substrate capable of dissipating heat;
an LED die located on the substrate and operable to emit light;
an optically reflective structure that is electrically insulative and located on the substrate and structured to form an optically reflective cavity around the LED die to confine the LED die;
an electrically conductive line structured at least partially within the optically reflective structure and electrically connected to the LED die for electrically driving the LED die to emit the light;
a phosphor material located to receive light emitted by the LED die to emit light under optical excitation of the light from the LED die; and
an optical element placed in an optical path of the light emitted by the phosphor material to produce better directionality of the emitted light than directionality of emitted light by the phosphor material without the optical element.

2. The device as in claim 1, wherein the substrate includes a thermal expansion coefficient substantially the same as the material forming the bottom surface of the LED die in contact with the substrate.

3. The device as in claim 1, wherein the optically reflective structure reflects visible light with greater than 90% reflectivity.

4. The device as in claim 1, wherein the optically reflective cavity confines the LED die within an area that is less than 15% than that of the LED die on the substrate.

5. The device as in claim 1, wherein the optically reflective structure includes a height larger than that of the LED die, and the phosphor material is located on top of the LED die and within the optically reflective cavity.

6. The device as in claim 5, wherein the optical element is confined within the optically reflective cavity and covers an opening in the optically reflective cavity existing between the LED die and the optically reflective structure.

7. The device as in claim 1, wherein the optical element covers at least a portion of the top surface of the optically reflective structure.

8. The device as in claim 1, wherein the optical element includes a thin transparent material layer coupled to the upper surface of the phosphors material and plural optical structures over the thin transparent material layer.

9. The device as in claim 1, wherein the electrically conductive line is electrically connected to the LED die via wire bonding.

10. The device as in claim 9, wherein the optically reflective structure includes an outer slot adjacent to the optically reflective cavity and providing an opening above at least a portion of the electrically conductive line to allow the electrically conductive line to be wire bonded to the LED die.

11. The device as in claim 1, wherein the electrically conductive line spans from a terminus at the optically reflective cavity to a terminus along an outer surface of the optically reflective structure.

12. The device as in claim 11, further comprising an electrode structure electrically coupled to the electrically conductive line at the terminus along the outer surface.

13. The device as in claim 1, wherein the optical element is separated from the phosphor material by a gap region between them.

14. The device as in claim 13, wherein the gap region includes a distance between the phosphor material and the optical element that is less than a quarter of a height of the LED die from the substrate.

15. The device as in claim 1, wherein the LED lighting device includes two or more LEDs configured in the optically reflective cavity, the LED lighting device implemented in an automotive headlamp.

16. The device as in claim 15, wherein the LED lighting device includes four LEDs to produce at least 1,200 lm light from the automotive headlamp, wherein the four LEDs are configured as 60 mil blue GaN LEDs and are capable of producing at least one of a lumen efficacy greater than 100 lm/W per LED, a lumen output of at least 300 lm per LED, or a current density of 500 mA/mm² per LED.

17. The device as in claim 15, wherein the LED lighting device includes two LEDs to produce at least 1,200 lm light from the automotive headlamp, wherein the two LEDs are configured as 85 mil blue GaN LEDs and are capable of producing at least one of a lumen efficacy greater than 100 lm/W per LED, a lumen output of at least 600 lm per LED, or a current density of 500 mA/mm² per LED.

18. The device as in claim 15, wherein the LED lighting device includes eight LEDs to produce at least 1,200 lm light from the automotive headlamp, wherein the eight LEDs are configured as 40 mil blue GaN LEDs and are capable of producing at least one of a lumen efficacy greater than 100 lm/W per LED, a lumen output of at least 150 lm per LED, or a current density of 500 mA/mm² per LED.

19. A packaging device for a light-emitting diode (LED) lighting device, the packaging device comprising:
a substrate capable of dissipating heat, the substrate including a region to support one or more LED chips or dies;
an optically reflective structure that is electrically insulative on the substrate, the optically reflective structure including a channel at least partially within its interior and a hole that forms an optically reflective well to confine the region to support one or more LED chips or dies, wherein the optically reflective well includes an area greater than that of the region and a height greater than that of an LED chip or die placed in the region, wherein the channel spans from the hole to an outer surface of the optically reflective structure;
an electrically conductive line within the channel of the optically reflective structure, the electrically conductive line, when electrically connected, to provide electrical current to the LED chip or die placed in the region for electrically driving the LED chip or die to emit the light;
a wavelength conversion material located within the optically reflective well and above the region, such that when the LED chip or die is placed in the region and operable to emit the light, the wavelength conversion material is capable of receiving the light emitted by the LED chip or die to emit light of one or more different wavelengths than the light emitted from the LED chip or die; and
a beam-shaping optical element located in an optical path of the emitted light by the wavelength conversion material to produce better directionality of the emitted light than directionality of emitted light by the wavelength conversion material without the beam-shaping optical element.

20. The packaging device as in claim 19, further comprising an electrode structure electrically coupled to the electrically conductive line at a terminus along the outer surface.

21. The packaging device as in claim 19, wherein the beam-shaping optical element is separated from the wavelength conversion material by a gap region between them.

22. The packaging device as in claim 19, wherein the optically reflective structure is formed of a material including at least one of a plastic material mixed with a titanium oxide (TiO₂) constituent, a white ceramic material with an outer TiO₂ coating, or a white Teflon material.

23. A method to fabricate an LED lighting device capable of producing high optical brightness, the method comprising:
forming an LED die over a substrate capable of dissipating heat;
placing an optically reflective material that is electrically insulative on the substrate, the optically reflective material including an electrically conductive line located within and a hole placed over the LED die to form an optically reflective well that confines the LED die, wherein an area of the optically reflective well is greater than that of the LED die on the substrate and the optically reflective well includes a height greater than that of the LED die, wherein the electrically conductive line spans from a terminus at the hole to a terminus along an outer surface of the optically reflective material;
electrically connecting the electrically conductive line to the LED die;
depositing a layer of a wavelength conversion material on top of the LED die such that the layer is confined within the optically reflective well; and
attaching a beam-shaping optics element formed of a thin layer of a transparent material with plural optical structures over the upper surface of the wavelength conversion material.

24. The method as in claim 23, wherein the depositing the layer of the wavelength conversion material covers an opening in the optically reflective well existing between the LED die and the optically reflective material.

25. The method as in claim 24, wherein the attaching the beam-shaping optics element covers at least a portion of the top surface of the optically reflective material.

26. The method as in claim 24, wherein the attaching the beam-shaping optics element is also confined within the optically reflective well and covers the opening in the optically reflective well existing between the LED die and the optically reflective material.

27. The method as in claim 23, wherein the beam-shaping optics element is separated from the wavelength conversion material by a gap area between them.

28. The method as in claim 27, wherein the gap area includes a distance between the wavelength conversion material and the beam-shaping optics element that is less than a quarter of a height of the LED die from the substrate.

29. The method as in claim 23, wherein the electrically connecting includes wire bonding the electrically conductive line to the LED die.

30. A method to fabricate a high brightness LED lighting device, the method comprising:
forming an LED die over a substrate capable of dissipating heat;
forming electrically conductive lines on the substrate;
placing an optically reflective material that is electrically insulative on the substrate, the optically reflective material including a channel on the bottom surface located over the electrically conductive lines and a hole placed over the LED die to form an optically reflective well that confines the LED die, wherein an area of the optically reflective well is greater than that of the LED die on the substrate and the optically reflective well includes a height greater than that of the LED die, wherein the electrically conductive line spans through the channel from a terminus at the hole to a terminus along an outer surface of the optically reflective material;
electrically connecting the electrically conductive line to the LED die;
depositing a layer of a wavelength conversion material on top of the LED die such that the layer is confined within the optically reflective well; and
attaching a beam-shaping optics element formed of a thin layer of a transparent material with plural optical structures over the upper surface of the wavelength conversion material.

31. The method as in claim 30, wherein the depositing the layer of the wavelength conversion material covers an opening in the optically reflective well existing between the LED die and the optically reflective material.

32. The method as in claim 31, wherein the attaching the beam-shaping optics element covers at least a portion of the top surface of the optically reflective material.

33. The method as in claim 31, wherein the attaching the beam-shaping optics element is also confined within the optically reflective well and covers the opening in the optically reflective well existing between the LED die and the optically reflective material.

34. The method as in claim 30, wherein the beam-shaping optics element is separated from the wavelength conversion material by a gap area between them.

35. The method as in claim 34, wherein the gap area includes a distance between the wavelength conversion material and the beam-shaping optics element that is less than a quarter of a height of the LED die from the substrate.

36. The method as in claim 30, wherein the electrically connecting includes wire bonding the electrically conductive line to the LED die.
